(19) United States
(12) Patent Application Publication
(10) Pub. No.: US 2010/0219478 A1
(43) Pub. Date: Sep. 2, 2010

(54) MOSFET, METHOD OF FABRICATING THE SAME, CMOSFET, AND METHOD OF FABRICATING THE SAME

(75) Inventors: Kenzo Manabe, Tokyo (JP); Nobuyuki Ikarashi, Tokyo (JP)

Correspondence Address: YOUNG & THOMPSON, 209 Madison Street, Suite 500, Alexandria, VA, 22314, US

(73) Assignee: NEC Corporation, Tokyo (JP)

(21) Appl. No.: 12/159,295

(22) PCT Filed: Dec. 25, 2006
(86) PCT No.: PCT/JP2006/325790

§ 371 Date: Jun. 26, 2008

(30) Foreign Application Priority Data
Dec. 26, 2005 (JP) 2005-372462

(51) Int. Cl. H01L 29/78; H01L 21/336; H01L 21/8238

(52) U.S. Cl. 257/369; 257/412; 438/303; 438/232; 257/411; 257/E29.255; 257/E21.409; 257/E21.632

(57) ABSTRACT

The present invention provides an NMOSFET including a semiconductor substrate, a gate insulating film formed on the semiconductor substrate, and a first gate electrode formed on the gate insulating film. The first gate electrode is composed of silicide of a metal M, and at least one element selected as an impurity from a group consisting of sulfur (S), fluorine (F) and chlorine (Cl). The impurity exists as an impurity layer at a surface of the first gate electrode at which the first gate electrode makes contact with the gate insulating film.

### BACKGROUND OF THE INVENTION

1. Field of the Invention

The present invention relates to a NMOSFET including a full silicide gate electrode containing impurity therein, a method of fabricating the same, a CMOSFET, and a method of fabricating the same. The present invention relates more particularly to enhancement in performance and reliability of a NMOSFET (N Metal Oxide Semiconductor Field Effect Transistor)

2. Description of the Related Art

In recent development of MOS (Metal Oxide Semiconductor) in which a transistor is fabricated smaller and smaller in size, there is caused a problem that a drive current is deteriorated due to depletion of a polysilicon (poly-Si) electrode.

Thus, some attempts have been made for avoiding deterioration of a driver current by preventing depletion of an electrode by virtue of a metal gate electrode.

In such attempts, a metal gate electrode is composed of pure metal, metal nitride or silicide. Even if a metal gate electrode is composed of any material, it is required that a threshold voltage (Vth) of a NMOSFET can be set equal to a predetermined voltage.

A high-performance NMOSFET is required that a threshold voltage (Vth) is set as low as possible. It was possible for a conventional NMOSFET to have a threshold voltage (Vth) of about 0.3 V.

However, a high-performance NMOSFET is recently required to further lower a threshold voltage (Vth). Specifically, followings are presently required.

In order to lower a threshold voltage (Vth) to about ±0.1 V, it was necessary for a gate electrode to be composed of a material having an effective work function of 4.2 eV or smaller.

In order to make is possible to readily control an effective work function of a material of which a gate electrode is composed, a full silicide gate electrode recently attracts attention. Herein, a full silicide gate electrode is comprised of a polysilicon (poly-Si) electrode turned into silicide with nickel (Ni), hafnium (Hf) or tungsten (W).

For instance, U.S. Pat. No. 50,064,636 suggests an NMOSFET including a gate insulating film comprised of a silicon dioxide (SiO₂) film, and a gate electrode comprised of a Ni silicide electrode fabricated by fully turning a polysilicon (poly-Si) electrode into which an impurity such as P and B, into silicide with nickel (Ni).

The above-mentioned United States Patent discloses (1) a process for fabricating the above-mentioned NMOSFET has much consistency with a conventional process for fabricating a MOS, and (2) it is possible to control a threshold voltage by dosing an impurity into polysilicon of which a gate pattern is composed, before silicidation for fabricating a gate electrode is carried out.

It is considered in view of the above-mentioned matters that a work function (a threshold voltage) of a full-silicide electrode can be readily controlled, and hence, full silicide is suitable to a material of which a metal gate electrode is composed. In particular, as mentioned above in the paragraph (2), it is quite effective to control a threshold voltage by dosing an impurity into a full-silicide electrode.

If impurities (N, P, As, Sb and Bi) having been employed in a process for fabricating a semiconductor device were dosed into a full-silicide electrode, it would be possible to have an effective work function in the range of about 4.2 to about 4.4 eV in a gate electrode used for an NMOSFET, resulting in that a threshold voltage can be controlled.

There has been recently suggested a process in which an effective work function for a gate electrode in an NMOSFET and an effective work function for a gate electrode in a PMOSFET are controlled independently of each other in a CMOSFET comprised of an NMOSFET and a PMOSFET. As a specific solution for accomplishing the process, there has been suggested a process in which gate electrodes of NMOSFET and PMOSFET are composed of metals or alloys different from each other and having different effective work functions from each other, to thereby control a threshold voltage (Vth) of a transistor (this process is called “dual metal gate process”).

For instance, a CMOS including an NMOSFET gate electrode composed of tantalum (Ta), and a PMOSFET gate electrode composed of ruthenium (Ru), both formed on a common SiO₂ film is suggested in “International electron device meeting technical digest 2002, p. 359”. It is described in the non-patent reference 1 that the NMOSFET gate electrode has an effective work function of 4.15 eV, the PMOSFET gate electrode has an effective work function of 4.95 eV, and thus, it is possible to modulate an effective work function by 0.8 eV between these two gate electrodes.

However, the above-mentioned arts are accompanied with a problem as follows.

In a case that, as suggested in U.S. Pat. No. 50,064,636, a nickel (Ni) silicide electrode into which an impurity such as phosphorus (P) and boron (B) is dosed is formed as a gate electrode on a gate insulating film composed of silicon dioxide (SiO₂), an effective work function of an NMOSFET gate electrode was in the range of about 4.2 to about 4.4 eV, as mentioned above. Accordingly, though it was possible to control a threshold voltage (Vth), there is a lower limitation in lowering a threshold voltage (Vth).

In a dual metal gate process in which gate electrodes of NMOSFET and PMOSFET are composed of different metal or alloys from each other having different work functions from each other, as suggested in “International electron device meeting technical digest 2002”, it is necessary to carry out an etching step for removing one or both of layers formed on gate patterns of NMOSFET and PMOSFET. This causes that a quality of a gate insulating film is degraded in the etching step, resulting in deterioration in performance and reliability of a resultant device.

### SUMMARY OF THE INVENTION

In view of the above-mentioned problems, it is an exemplary object of the present invention to provide an NMOSFET and a method of fabricating the same, both of which are capable of reducing a threshold voltage of an NMOSFET to about ±0.1 V to thereby enhance performance and reliability of a resultant device.

It is further an exemplary object of the present invention to provide a CMOSFET and a method of fabricating the same, both of which are capable of controlling threshold voltages (Vth) of an NMOSFET and a PMOSFET independently of each other without deterioration in performance and reliability of a resultant device.

As a result of various analysis, the inventors discovered that a threshold voltage (Vth) could be lowered to about ±0.1 V, which was almost impossible by the conventional techniques, by dosing sulfur (S), fluorine (F) or chlorine (Cl), all of which were not used as an impurity, into an NMOSFET gate electrode as an impurity, and by positioning the impurity at an interface between a gate electrode and a gate insulating film.

The inventors further discovered that, in a CMOSFET comprised of an NMOSFET and a PMOSFET, it was possible to prevent a material of which a gate electrode is composed from being degraded in fabrication of a CMOSFET, and to fabricate a CMOSFET having enhanced performance and reliability, by electrically connecting an NMOSFET gate electrode and a PMOSFET gate electrode with each other to thereby define a common line-shaped electrode, and once heating the gate electrodes to thereby render the gate electrodes to be composed of silicides identical with each other or similar to each other in composition.

Based on the above-mentioned discovery, the present invention provides an NMOSFET, a method of fabricating the same, a CMOSFET, and a method of fabricating the same, as follows.

In a first exemplary aspect of the present invention, the present invention provides an NMOSFET including a semiconductor substrate, a gate insulating film formed on the semiconductor substrate, and a first gate electrode formed on the gate insulating film, characterized in that the first gate electrode is composed of silicide of a metal, and at least one element selected as an impurity from a group consisting of sulfur (S), fluorine (F) and chlorine (Cl), and the impurity exists at least at an interface between the first gate electrode and the gate insulating film.

It is preferable that the gate insulating film is composed of oxide.

For instance, the gate insulating film is composed of silicon oxide or silicon oxynitride.

As an alternative, the gate insulating film may be composed of HfSiON.

The gate insulating film may be designed to have a multi-layered structure, in which case, the gate insulating film is comprised of, for instance, a first layer formed. in contact with the first gate electrode, and comprised of one of a silicon oxide layer, a silicon oxynitride layer, and a silicon nitride layer, and a second layer formed below the first layer, and composed of HfSiON.

If the first gate electrode contains fluorine (F), it is preferable that monovalent fluorine (F) existing at a surface making contact with the gate insulating film of the first gate electrode has a surface density at 9×10¹³ cm⁻² or greater.

If the first gate electrode contains sulfur (S), it is preferable that monovalent sulfur (S) existing at a surface making contact with the gate insulating film of the first gate electrode has a surface density at 1.1×10¹⁴ cm⁻² or greater.

If the first gate electrode contains chlorine (Cl), it is preferable that monovalent chlorine (Cl) existing at a surface making contact with the gate insulating film of the first gate electrode has a surface density at 1.3×10¹⁴ cm⁻² or greater.

It is preferable that the metal is turned into silicide at a temperature in the range of 350 to 500 degrees centigrade both inclusive.

The metal is at least one metal selected from a group consisting of nickel (Ni), platinum (Pt), tantalum (Ta), cobalt (Co), titanium (Ti), and tungsten (W), for instance.

It is preferable that the metal is nickel (Ni).

It is preferable that the impurity is distributed upwardly from the interface in a direction of a normal line of the semiconductor substrate.

The NMOSFET in accordance with the present invention is designed to have the following (1) and (2) structures.

(1) on a gate insulating film is formed a full-silicide electrode, as a first gate electrode, containing at least one element selected as an impurity from a group consisting of sulfur (S), fluorine (F) and chlorine (Cl).

(2) in the first gate electrode, the impurity exists at an interface between the full-silicide electrode (the first gate electrode) and the gate insulating film.

Various impurities have been conventionally employed as an impurity to dose into silicon (Si). However, sulfur (S), fluorine (F) and chlorine (Cl) have not been considered as an impurity.

Furthermore, a concentration profile of an impurity in a gate electrode has not been fully analyzed.

By virtue of the above-mentioned structures (1) and (2), the present invention makes it possible to make an effective work function of an NMOSFET gate electrode smaller than the same of a conventional NMOSFET, and further, to lower a threshold voltage of an NMOSFET.

In the specification the term “an effective work function” of a gate electrode includes consideration of influence exerted by dipole and Fermi level pining formed at fixed electric charge/interface in a gate insulating film, relative to a work function of a material of which a gate electrode is composed. In this meaning, “an effective work function” of a gate electrode is distinct from “a work function” of a material of which a gate electrode is composed.

“An effective work function” of a gate electrode can be calculated based on a flat band resulted from a C-V curve between a gate insulating film and a gate electrode.

In order to cause at least one impurity selected from a group consisting of sulfur (S), fluorine (F) and chlorine (Cl) to position at an interface between a full-silicide electrode (a first gate electrode) and a gate insulating film, the following process may be carried out, for instance.

First, a gate pattern comprised of a gate insulating film and polysilicon is formed on a semiconductor substrate. Then, ions of an impurity (sulfur (S), fluorine (F) or chlorine (Cl)) are implanted into the polysilicon.

Then, a film composed of a metal M is deposited on the gate pattern composed of the polysilicon. Then, the film and the gate pattern are heated to thereby cause react the polysilicon and the metal M with each other, resulting in that the gate pattern is turned into full silicide.

When the gate pattern is being turned into full silicide, the polysilicon defining the gate pattern is gradually turned into silicide of the metal M towards the gate insulating film in a thickness-wise direction (for instance, a direction indicated with an arrow 61 in FIGS. 1 and 7B).

As the gate pattern is being turned into full silicide, there occurs “snow plow” effect in which the impurity having been implanted into the polysilicon moves in the gate pattern towards the gate insulating film in a thickness-wise direction of the gate pattern, as if the impurity is pushed by silicide.

Thus, in accordance with the present invention, it is possible to move the impurity to an interface between a full-silicide electrode and a gate insulating film, and position the impurity at the interface, by optimally selecting a thickness of the metal M layer deposited on the gate pattern, a temperature and a period of time at and during which the gate pattern is turned into full silicide, a kind of an impurity, and other factors.

In the present invention, it is necessary for an impurity (S, F or Cl) to exist at least at a surface of a gate electrode making contact with a gate insulating film. As an alternative, an impurity may exist in a predetermined area of a gate electrode making contact with a gate insulating film. For instance, an impurity may exist in a predetermined area of a gate electrode upwardly extending from an interface between a gate electrode and a gate insulating film in a direction in which a normal line of a semiconductor substrate extends.

The inventors actually fabricated an NMOSFET for conducting an experiment to ensure that an impurity (S, F or Cl) existed at the interface, and the impurity provided advantages.

First, as illustrated in FIG. 2, an NMOSFET was fabricated in accordance with the above-mentioned process. The NMOSFET had a structure of (a first gate electrode)/(a gate insulating film)/(a semiconductor substrate), specifically, NiSi 50/SiO₂ (3 nm) 51/Si 52 into which sulfur (S) was implanted as an impurity. A plurality of such NMOSFETs was fabricated, changing the above-mentioned fabrication factors (a temperature and a period of time at and during which the gate pattern is turned into full silicide, a concentration of an impurity to be implanted into polysilicon).

Status of the impurity contained in a gate electrode in each of the NMOSFETs was measured by means of XPS (photo electron spectrometry).

The XPS measurement was carried out as follows.

First, CMP (Chemical Mechanical Polishing) and wet etching through the use of KOH solution were carried out at a rear surface of each of the NMOSFETs to thereby remove the silicon substrate 52. Thus, there were fabricated samples each having a structure of (a first gate electrode) (NiSi) 50/(a gate insulating film) (SiO₂) 51.

Then, as illustrated in FIG. 2, an X ray 53 was irradiated to the gate insulating film 51 for causing photo-electrons 54 to be emitted out of the sample, and the photo-electrons 54 of sulfur (S) having 2 s-orbit were measured.

The reason why the gate insulating film 51 was not removed in fabrication of the samples is that, if the gate insulating film 51 were removed, the first gate electrode 50 would be damaged at an interface at which the first gate electrode 50 makes contact with the gate insulating film 51, resulting in that it would be impossible to accurately measure status of the interface.

Furthermore, even if the gate insulating film 51 were not removed, since the gate insulating film (SiO₂) 51 has a thickness of about 3 nm, it would be possible to detect photo electrons emitted from an impurity existing at an interface between the first gate electrode 50 and the gate insulating film 51, by optimally determining conditions for carrying out XPS measurement or by optimally analyzing obtained data.

In the XPS measurement, there was used “QUANTUM 2000 ESCA system” commercially available from Albackfy. In the XPS measurement, Al-Kα rays as monochromatic lights were irradiated to the sample, and photo electrons 54 emitted from and perpendicularly to the sample were detected.

FIG. 3 illustrates an example of the result of the XPS measurement having been carried out to a plurality of the NMOSFET samples.

As illustrated in FIG. 3, in each of the NMOSFET samples, there was obtained, by virtue of the XPS measurement, spectrum comprised of a combination of four peaks caused by sulfur (S) electrons having 2 s-orbit. Each of the peaks corresponds to S⁰, S¹⁺, S²⁺ and S³⁺ (an exponent at a shoulder indicates an oxidation number) when observing from low energy with respect to the energy at a peak.

It is considered that the oxidation status (S¹⁺, S²⁺ and S³⁺) of an impurity is obtained because an impurity existing at an interface between the first gate electrode 50 and the gate insulating film 51 is influenced by elements of which the gate insulating film 51 is composed. The impurity is naturally oxidized as long as it exists at an interface between the first gate electrode 50 and the gate insulating film 51. In dependence on conditions for silicidation, composition of silicide, a sort(s) of an impurity (or impurities), and so on, an impurity having a predetermined oxidation number exists at a predetermined rate at an interface between the first gate electrode 50 and the gate insulating film 51. If the gate insulating film 51 contains oxygen therein, such an impurity is conspicuously oxidized.

In addition, a surface density of each of S⁰, S¹⁺, S²⁺ and S³⁺ at an interface between the first gate electrode 50 and the gate insulating film 51 was measured by means of TEM-EELS (TEM: Transmission Electron Microscope, EELS: Electron Energy-Loss Spectroscopy), as well as carrying out XPS (photo electron spectrometry) measurement.

In accordance with the TEM-EELS measurement, it is possible to measure a surface density of each of S⁰, S¹⁺, S²⁺ and S³⁺ at an interface between the first gate electrode 50 and the gate insulating film 51, by optimally determining measurement conditions.

The TEM-EELS measurement results were coincident with surface densities calculated based on the peak intensities (the peaks illustrated in FIG. 3) having been obtained by the XPS measurement.

Furthermore, there was measured an effective work function for each of the NMOSFET samples having been fabricated in different conditions from one another.

The inventors calculated a relationship between a surface density of each of S⁰, S¹⁺, S²⁺ and S³⁺ in each of the NMOSFET samples, and the measured effective work function (threshold voltage).

The relationship indicates that a surface density of S¹⁺ varies in all of the NMOSFET samples having a varied effective work function (threshold voltage), and that a surface density of each of S⁰, S²⁺ and S³⁺ does hardly vary. Thus, the inventors concluded that an effective work function (a threshold voltage) is dependent principally on a surface density of S¹⁺.

Furthermore, there were fabricated NMOSFET samples under varied fabrication conditions with respect to fluorine (F) and chlorine (Cl), similarly to the sulfur (S) case, and there were carried out measurement of an effective work function (a threshold voltage), measurement of oxidation statuses of an impurity by virtue of XPS measurement, calculation of a surface density in each oxidation statuses, and measurement of a surface density in each of oxidation statuses by virtue of TEM-EELS measurement.

As a result, it was discovered that a surface density calculated based on XPS measurement and a surface density calculated based on TEM-EELS measurement are coincident with each other, and an effective work function (a threshold voltage) varies in dependence only on a surface density of monovalent impurities F¹⁺ and Cl¹⁺ being in oxidized condition and existing at an interface between the first gate electrode 50 and the gate insulating film 51.

As mentioned above, an impurity existing at an interface between the first gate electrode 50 and the gate insulating film 51 is always turned into a monovalent oxidized impurity at a predetermined rate. Accordingly, it is possible to control an effective work function (a threshold voltage) in the present invention by causing an impurity to exist at an interface between the first gate electrode 50 and the gate insulating film 51.

The NMOSFET in accordance with the present invention includes a gate insulating film composed of SiO₂ or SiON, and a first gate electrode composed of Ni silicide into which an impurity is implanted and formed on the gate insulating film. FIG. 4 is a graph indicating a relation in the NMOSFET in accordance with the present invention between an effective work function of the first gate electrode and a surface density of each of monovalent oxidized impurities (Sb¹⁺, S¹⁺, F¹⁺ and Cl¹⁺) existing at interface between the first gate electrode 50 and the gate insulating film 51.

It is understood in light of FIG. 4 that the impurities S¹⁺, F¹⁺ and Cl¹⁺ can provide a smaller effective work function than Sb¹⁺ which can minimize an effective work function among conventionally used impurities, even if they have the same surface density as one another.

In particular, it is understood that, assuming that S¹⁺, F¹⁺ and Cl¹⁺ have the same surface density as one another, the impurity F provides a minimum effective work function.

It is further understood in light of FIG. 4 that if fluorine (F) having a surface density of 9×10¹³ cm⁻² (indicated as 0.09×10¹⁵ cm⁻² in FIG. 4) or greater were used as an impurity, it is possible to accomplish an effective work function of 4.2 eV or lower which is necessary for a high-performance NMOSFET device.

Similarly, it is further understood that if sulfur (S) having a surface density of 1.1×10¹⁴ cm⁻² (indicated as 0.11×10¹⁵ cm⁻² in FIG. 4) or greater were used as an impurity, or if chlorine (Cl) having a surface density of 1.3×10¹⁴ cm⁻² (indicated as 0.13×10¹⁵ cm⁻² in FIG. 4) or greater were used as an impurity, it is possible to accomplish an effective work function of 4.2 eV or lower which is necessary for a high-performance NMOSFET device.

That is, in an NMOSFET including a gate electrode composed of Ni silicide into which sulfur (S), fluorine (F) or chlorine (Cl) is implanted, it is preferable that fluorine (F) existing at interface between the first gate electrode and the gate insulating film has a surface density of 9×10¹³ cm⁻² or greater, sulfur (S) existing at interface between the first gate electrode and the gate insulating film has a surface density of 1.1×10¹⁴ cm⁻² or greater, and chlorine (Cl) existing at interface between the first gate electrode and the gate insulating film has a surface density of 1.3×10¹⁴ cm⁻².

It is possible to control a surface density of a monovalent oxidized impurity by optimally controlling fabrication conditions such as a temperature and a period of time at and during which a metal of which the first gate electrode is composed is turned into silicide, composition of silicide of which the first gate electrode is composed, a sort and a concentration of an impurity, and so on.

FIG. 5 is a graph indicating a relation between a concentration (in the unit of cm⁻³) of an impurity implanted into a channel, and a threshold voltage (Vth) (in the unit of V) which is expected for an NMOSFET to have based on an effective work function corresponding to the concentration of an impurity, in an NMOSFET including a gate oxide film (SiO₂ or SiON) having a thickness of 1.8 nm, and a first gate electrode composed of NiSi into which fluorine (F) is implanted as an impurity.

As is obvious in light of FIG. 5, it is possible, at a channel concentration (1×10¹⁷ cm⁻³ to 1×10¹⁸ cm⁻³) selected in a conventional NMOSFET device, to accomplish a high-performance NMOSFET having a low threshold voltage, specifically, a threshold voltage of about 0.1 V which was impossible to accomplish in a NiSi electrode (a gate electrode) into which a conventional impurity is implanted, by employing a first gate electrode having a effective work function controlled to be equal to or smaller than 4.2 eV by implanting F into NiSi as an impurity.

In a second exemplary aspect of the present invention, the present invention provides a method of fabricating an NMOSFET, including a first step of forming an electrically insulating layer on a semiconductor substrate, a second step of forming a polysilicon layer on the electrically insulating layer, a third step of dosing at least one element selected as an impurity from a group consisting of sulfur (S), fluorine (F) and chlorine (Cl), into the polysilicon layer to thereby turn the polysilicon layer into an impurity-containing polysilicon layer, a fourth step of patterning the electrically insulating layer and the impurity-containing polysilicon layer into a gate pattern, a fifth step of depositing a metal layer on the gate pattern, a sixth step of heating the metal and the impurity-containing polysilicon layer to thereby cause the metal to react with impurity-containing polysilicon included in the impurity-containing polysilicon layer, to thereby turn the metal into metal silicide containing an impurity therein, and a seventh step of removing a portion of the metal which did not react with the impurity-containing polysilicon in the sixth step.

The method of fabricating an NMOSFET, in accordance with the present invention, may further include an eighth step of forming source/drain regions, and a ninth step of forming silicide on the source/drain regions, in which case, the eighth and ninth steps are carried out prior to the sixth step, and the heating is carried out at the sixth step at such a temperature that an electrical resistance of the silicide formed on the source/drain regions is not raised.

The method of fabricating an NMOSFET, in accordance with the present invention, may further include a tenth step of forming source/drain regions prior to carrying out the sixth step, and an eleventh step of forming silicide on the source/drain regions after the sixth step was carried out.

In the method of fabricating an NMOSFET, in accordance with the present invention, it is preferable that the impurity is dosed into the polysilicon layer in the third step by ion implantation.

In the case that silicide (second silicidation) is formed on source/drain regions before turning a gate electrode into silicide (first silicidation) (the ninth step), it is preferable that a metal to be deposited on a gate pattern in the fifth step is able to cause polysilicon (poly-Si) to completely turn into silicide at a low temperature. By selecting a metal enabling to carry out a low-temperature salicidation process, as a metal to be deposited on a gate pattern, it is possible to prevent a silicide layer formed on source/drain regions from turning into a material having a electrically high resistance, ensuring that the silicide layer can avoid to have a high resistance.

Specifically, it is preferable to select a metal which is completely turned into silicide at a temperature in the range of 350 to 500 degrees centigrade during which an electrical resistance of a metal silicide formed on source/drain diffusion layers does not increase. By turning a polysilicon (poly-Si) electrode into silicide with such a metal, it would be possible to determine a composition of an electrode in a self-aligning manner, and avoid fluctuation in a fabrication process.

Thus, it is preferable to select nickel (Ni), platinum (Pt), tantalum (Ta), cobalt (Co) or titanium (Ti) as a metal turning into silicide. It is more preferable to select nickel (Ni). It is possible to completely turn polysilicon (poly-Si) into silicide with nickel (Ni) by annealing the polysilicon at 450 degrees centigrade or lower.

In the case that silicide (third silicidation) is formed on source/drain regions after turning a first gate electrode into silicide (first silicidation) (the eleventh step), since a silicide layer is not yet formed on source/drain regions, the heating conditions for carrying out the first silicidation are not to be limited to specific conditions, unless an impurity having been implanted into source/drain regions and/or a channel region is re-diffused. Accordingly, it is possible to select a metal out of a wide range of metals for forming a silicide layer on source/drain regions.

In a third exemplary aspect of the present invention, the present invention further provides a CMOSFET including an NMOSFET as set forth in any one of claims 1 to 12, and a PMOSFET which includes a semiconductor substrate, a gate insulating film formed on the semiconductor substrate, and a second gate electrode formed on the gate insulating film, characterized in that the NMOSFET and the PMOSFET are arranged such that length-wise directions of gates are parallel with each other, the second gate electrode includes silicide of the metal, and an impurity, and the first and second gate electrodes are electrically connected with each other, and define a line-shaped electrode extending perpendicularly to the length-wise direction of a gate of the NMOSFET.

In a fourth exemplary aspect of the present invention, the present invention further provides a method of fabricating a CMOSFET including an NMOSFET and a PMOSFET, including a first step of forming an electrically insulating layer on a semiconductor substrate, a second step of forming a polysilicon layer on the electrically insulating layer, a third step of dosing at least one element selected as an impurity from a group consisting of sulfur (S), fluorine (F) and chlorine (Cl), into the polysilicon layer in a region in which the NMOSFET is to be fabricated, to thereby turn the polysilicon layer into an impurity-containing polysilicon layer, a fourth step of dosing a p-type impurity into the polysilicon layer in a region in which the PMOSFET is to be fabricated, to thereby turn the polysilicon layer into an impurity-containing polysilicon layer, a fifth step of patterning the electrically insulating layer and the impurity-containing polysilicon layer into a gate pattern, a sixth step of depositing a metal layer on the gate pattern, a seventh step of heating the metal and the impurity-containing polysilicon layer to thereby cause the metal to react with impurity-containing polysilicon included in the impurity-containing polysilicon layer, to thereby turn the metal into metal silicide containing an impurity therein, and an eighth step of removing a portion of the metal which did not react with the impurity-containing polysilicon in the seventh step.

It is preferable that a first gate electrode of the NMOSFET and a second gate electrode of the PMOSFET are fabricated such that length-wise directions of gates of the NMOSFET and the PMOSFET are parallel with each other, and the first and second gate electrodes are electrically connected with each other, and define a line-shaped electrode extending perpendicularly to the length-wise direction of a gate of the NMOSFET.

The above and other objects and advantageous features of the present invention will be made apparent from the following description made with reference to the accompanying drawings, in which like reference characters designate the same or similar parts throughout the drawings.

### BRIEF DESCRIPTION OF THE DRAWINGS

FIG. 1 is a cross-sectional view illustrating a structure of the NMOSFET in accordance with the first exemplary embodiment of the present invention.

FIG. 2 is a cross-sectional view showing XPS measurement carried out to the NMOSFET in accordance with the present invention.

FIG. 3 is a graph showing the results of the XPS measurement carried out to the NMOSFET in accordance with the present invention.

FIG. 4 is a graph showing the relation between an effective work function of a gate electrode in the NMOSFET in accordance with the present invention, and a surface density of an impurity existing at an interface between a gate electrode and a gate insulating film.

FIG. 5 is a graph indicating the relation between a concentration of an impurity implanted into a channel in the NMOSFET in accordance with the present invention, and a threshold voltage (Vth) expected for the NMOSFET to have based on an effective work function corresponding to the concentration of an impurity.

FIGS. 6A to 6H are cross-sectional views each illustrating respective step in a method of fabricating the CMOSFET, in accordance with the third exemplary embodiment of the present invention.

FIGS. 7A and 7B are cross-sectional views each illustrating respective step in a method of fabricating the CMOSFET, in accordance with the third exemplary embodiment of the present invention.

FIG. 8 is a graph showing the characteristic between a drain current and a gate voltage in the NMOSFET in accordance with the present invention.

FIGS. 9A to 9H are cross-sectional views each illustrating respective step in a method of fabricating the CMOSFET, in accordance with the fourth exemplary embodiment of the present invention.

FIGS. 10A to 10C are cross-sectional views each illustrating respective step in a method of fabricating the CMOSFET, in accordance with the fourth exemplary embodiment of the present invention.

FIGS. 11A to 11C are cross-sectional views each illustrating respective step in a method of fabricating the CMOSFET, in accordance with the fourth exemplary embodiment of the present invention.

FIG. 12A is a plan view of the CMOSFET in accordance with the second exemplary embodiment of the present invention.

FIG. 12B is a cross-sectional view taken along the line A-A′ in FIG. 12A.

FIG. 12C is a combination of a cross-sectional view taken along the line B-B′ in FIG. 12A and a cross-sectional view taken along the line C-C′ in FIG. 12A.

### DESCRIPTION OF THE EXEMPLARY EMBODIMENTS

### First Exemplary Embodiment

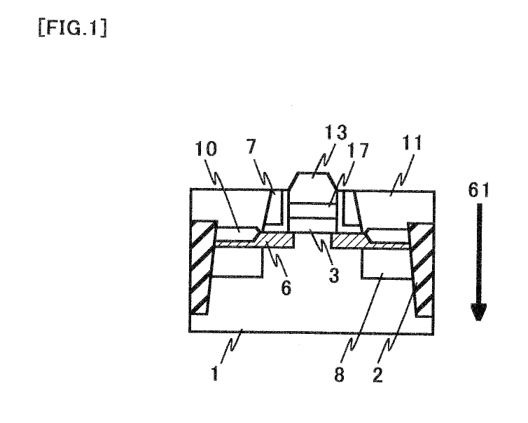

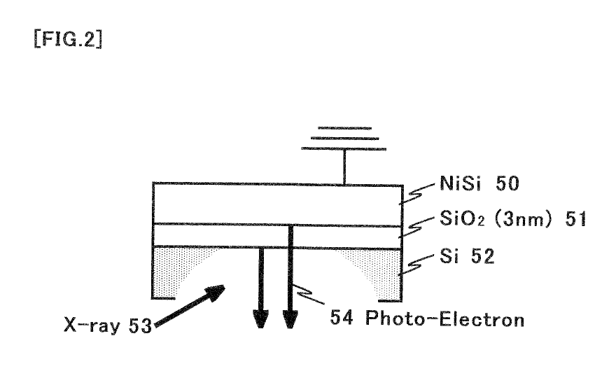

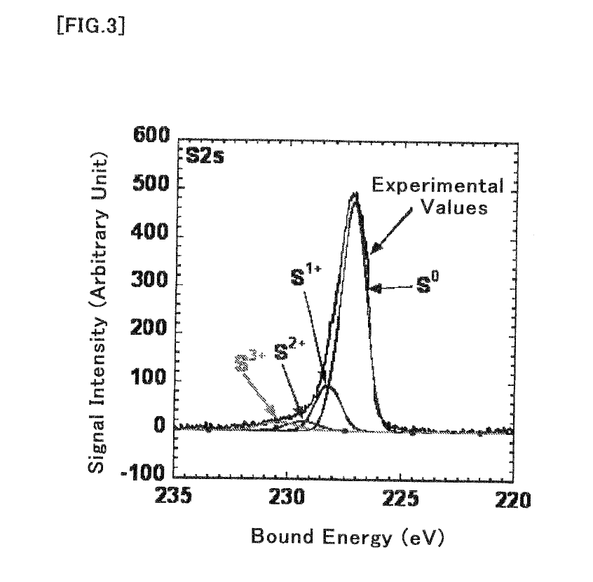

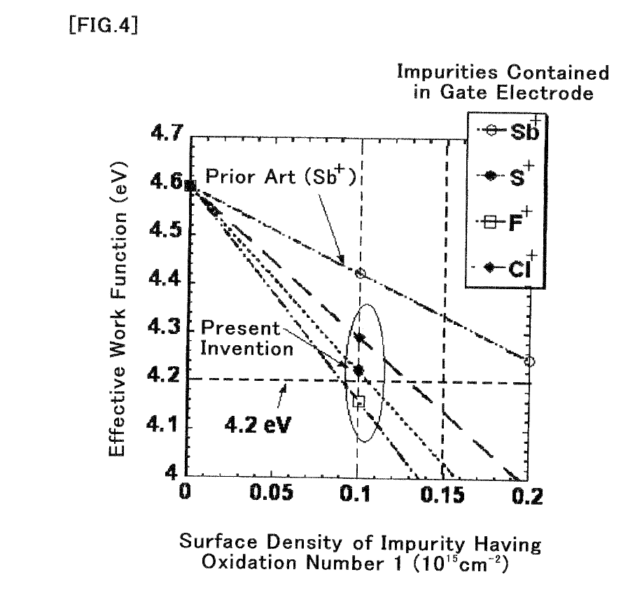

FIG. 1 is a cross-sectional view illustrating a structure of an NMOSFET in accordance with the first exemplary embodiment of the present invention.

As illustrated in FIG. 1, the NMOSFET in accordance with the first exemplary embodiment includes a silicon substrate 1, a device separation area 2 formed in the silicon substrate 1, a gate insulating film 3 formed in a p-type region (p-type semiconductor region or p-type well) defined by the device separation area 2, a first gate electrode 13 formed on the gate insulating film 3, a gate sidewall spacer 7 covering a sidewall of the first gate electrode 13 therewith, source/drain regions 8 formed in the silicon substrate 1 to sandwich the p-type region therebetween, extended diffusion layers 6 extending towards the first gate electrode 13 from the source/drain regions 8, silicide layers 10 formed on the extended diffusion layers 6, and an interlayer insulating film 11 formed on the silicide layers 10.

The first gate electrode 13 includes a layer 17 at an interface at which the first gate electrode 13 makes contact with the gate insulating film 3. The layer 17 contains at least one impurity selected from a group consisting of sulfur (S), fluorine (F) and chlorine (Cl).

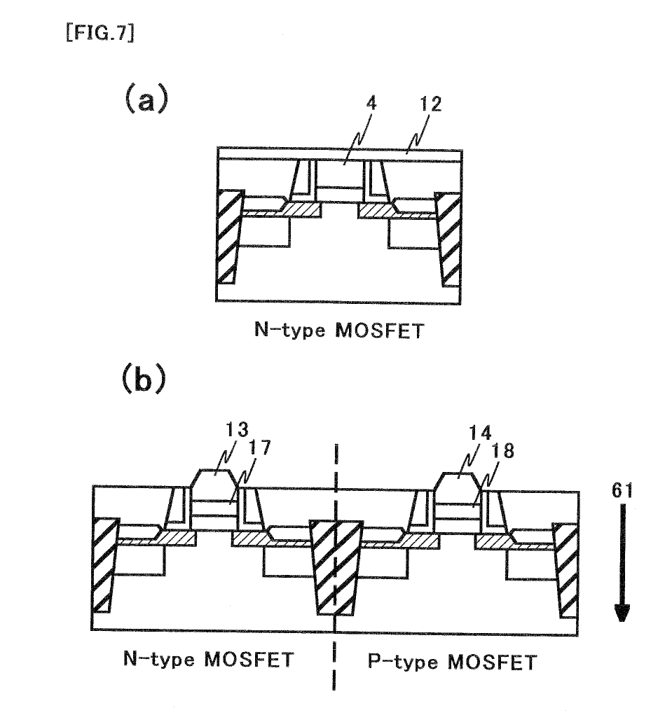

In FIG. 1, a region in which an impurity exists at a high concentration is indicated as the layer 17. In the actual first gate electrode 13, a concentration of an impurity is distributed continuously or intermittently in a thickness-wise direction of the first gate electrode 13. As an alternative, an impurity is distributed in a thickness-wise direction of the first gate electrode 13. Hereinbelow, the layer 17 means the same with respect to FIGS. 7A, 7B, 10 and 11.

By designing the first gate electrode 13 to include the layer 17 in which at least one impurity selected from a group consisting of sulfur (S), fluorine (F) and chlorine (Cl) exists, at an interface at which the first gate electrode 13 makes contact with the gate insulating film 3, it is possible not only to avoid depletion of the first gate electrode 13, but also to keep a threshold voltage of an NMOSFET low, which was quite difficult to accomplish in prior art, ensuring a high-performance transistor having high reproducibility and reliability.

It is preferable to use nickel (Ni) as the metal M.

Since nickel (Ni) has superior controllability of a threshold voltage (Vth), it is possible to accomplish a small threshold voltage (Vth) by using nickel (Ni) as the metal M.

As silicide of the metal M, there may be selected Ni₃Si, Ni₂Si, NiSi or NiSi₂,

It is preferable that the gate insulating film 3 in the NMOSFET in accordance with the first exemplary embodiment is composed of oxide.

By composing the gate insulating film of oxide, when the first gate electrode 13 for the NMOSFET is formed (that is, when silicidation is carried out), it is possible to cause an impurity implanted into a gate pattern to react with oxygen to thereby form a monovalent impurity at an interface between the first gate electrode 13 and the gate insulating film 3.

It is preferable that the gate insulating film 3 is comprised of a silicon oxide film or a silicon oxynitride film. These films are superior in film uniformity and stability.

Furthermore, it is preferable that the gate insulating film 3 is comprised of a HfSiON film.

By employing this gate insulating film having a high dielectric constant, it is possible to reduce a gate leak current. A degree by which a threshold voltage is reduced is smaller in a transistor including the gate insulating film 3 comprised of a HfSiON film than in a transistor including the gate insulating film 3 comprised of a silicon oxide film or a silicon oxynitride film.

It is possible to make an effective work function smaller by designing the gate insulating film 3 to have a multi-layered structure, forming a silicon oxide layer, a silicon oxynitride layer or a silicon nitride layer as a layer making contact with the first gate electrode 13, and forming a HfSiON layer below the layer. Thus, it is possible to accomplish a low threshold voltage in the NMOSFET in accordance with the first exemplary embodiment.

### Second Exemplary Embodiment

A CMOSFET can be fabricated by combining a PMOSFET with the NMOSFET in accordance with the above-mentioned first exemplary embodiment.

The second exemplary embodiment in accordance with the present invention relates to such a CMOSFET.

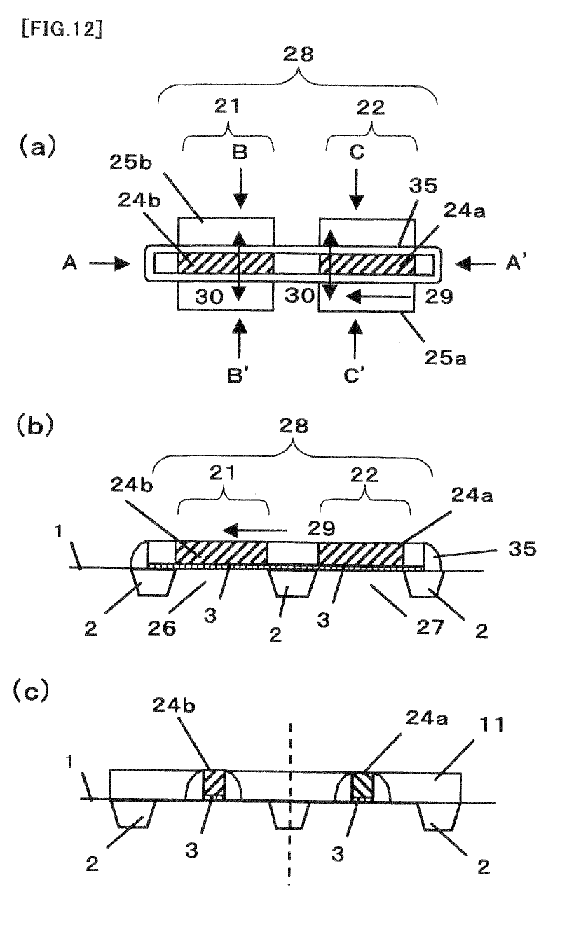

FIGS. 12A to 12C illustrate a CMOSFET in accordance with the second exemplary embodiment of the present invention. FIG. 12A is a plan view of the CMOSFET in accordance with the second exemplary embodiment, FIG. 12B is a cross-sectional view taken along the line A-A′ in FIG. 12A, and FIG. 12C is a combination of a cross-sectional view taken along the line B-B′ in FIG. 12A and a cross-sectional view taken along the line C-C′ in FIG. 12A.

It should be noted that FIG. 12C is a combination of cross-sectional views of an NMOSFET and a PMOSFET as viewed in different cross-sections, and is not a cross-sectional view obtained when viewed the CMOSFET in a single cross-section. A central broken line in FIG. 12C indicates that an NMOSFET and a PMOSFET are viewed in different cross-sections from each other. The same is applied to FIGS. 7B, 10A to 10C, and 11A to 11C.

As illustrated in FIGS. 12A and 12B, the CMOSFET in accordance with the second exemplary embodiment includes an NMOSFET 21 and a PMOSFET 22.

Specifically, the CMOSFET in accordance with the second exemplary embodiment includes a silicon substrate 1, a device separation area 2 formed in the silicon substrate 1, a p-type region (p-type semiconductor region or p-type well) 26 defined by the device separation area 2 in the semiconductor substrate 1, an n-type region (n-type semiconductor region or n-type well) 27 defined by the device separation area 2 in the semiconductor substrate 1, a gate insulating film 3 formed on both the p-type region 26 and the n-type region 27, a first gate electrode 24b formed on the gate insulating film 3 above the p-type region 26, a second gate electrode 24a formed on the gate insulating film 3 above the n-type region 27, gate sidewall spacers 35 covering sidewalls of the first gate electrode 24b and the second gate electrode 24a therewith, source/drain regions 25b formed in the silicon substrate 1 to sandwich the p-type region 26 therebetween, source/drain regions 25a formed in the silicon substrate 1 to sandwich the n-type region 27 therebetween, and an interlayer insulating film 11 (see FIG. 12C) formed on the semiconductor substrate 1, covering the sidewall spacers 35 therewith.

The NMOSFET 21 is defined by the p-type region 26, the gate insulating film 3, the first gate electrode 24b, the source/drain regions 25b, and the gate sidewall spacer 35. The PMOSFET 22 is defined by the n-type region 27, the gate insulating film 3, the second gate electrode 24a, the source/drain regions 25a, and the gate sidewall spacer 35.

As illustrated in FIGS. 12A and 12B, the CMOSFET in accordance with the second exemplary embodiment is designed to include a line-shaped electrode 28 extending in a direction indicated with an arrow 29 on an area from the n-type region 27 to the p-type region 26 via the device separation area 2. A portion of the line-shaped electrode 28 disposed on the n-type region 27 defines the second gate electrode 24a, and a portion of the line-shaped electrode 28 disposed on the p-type region 26 defines the first gate electrode 24b.

As illustrated in FIG. 12A, the NMOSFET 21 and the PMOSFET 22 are arranged such that length-wise directions 30 of their gates are parallel with each other.

The first gate electrode 24b and the second gate electrode 24a are electrically connected to each other through a silicide region disposed above the device separation area 2.

The line-shaped electrode 28 extends in a direction 29 perpendicular to the length-wise direction 30 of a gate of the NMOSFET 21.

It is preferable that both of the first gate electrode 24b and the second gate electrode 24a are composed of silicide of the metal M, in which case, a silicide composition (an atomic composition rate between the metal M and silicon (Si)) of the metal M of which the first gate electrode 24b may be identical with or may not be identical with a silicide composition of the metal M of which the second gate electrode 24a.

It is preferable that a silicide composition of the metal M of which the first gate electrode 24b is identical with a silicide composition of the metal M of which the second gate electrode 24a in order to prevent mutual diffusion of different materials of which two gate electrodes are composed when the metal is turned into silicide, and to ensure a gate electrode having uniformity and further having superior device performance. However, in this case, the second gate electrode 24a contains an impurity therein.

In the CMOSFET in accordance with the second exemplary embodiment, as illustrated in FIGS. 12A and 12B, the first gate electrode 24b and the second gate electrode 24a define a part of the line-shaped electrode 28.

Though it is preferable that both of the first gate electrode 24b and the second gate electrode 24a are composed of silicide of the metal M, the first gate electrode 24b and the second gate electrode 24a contain different impurities from each other. Accordingly, it is possible to entirely fabricate the line-shaped electrode 28 by single silicidation to thereby uniformize device characteristics of the first gate electrode 24b and the second gate electrode 24a, ensuring that the CMOSFET has high reliability.

### Third Exemplary Embodiment

The third exemplary embodiment in accordance with the present invention relates to a method of fabricating the CMOSFET in accordance with the second exemplary embodiment.

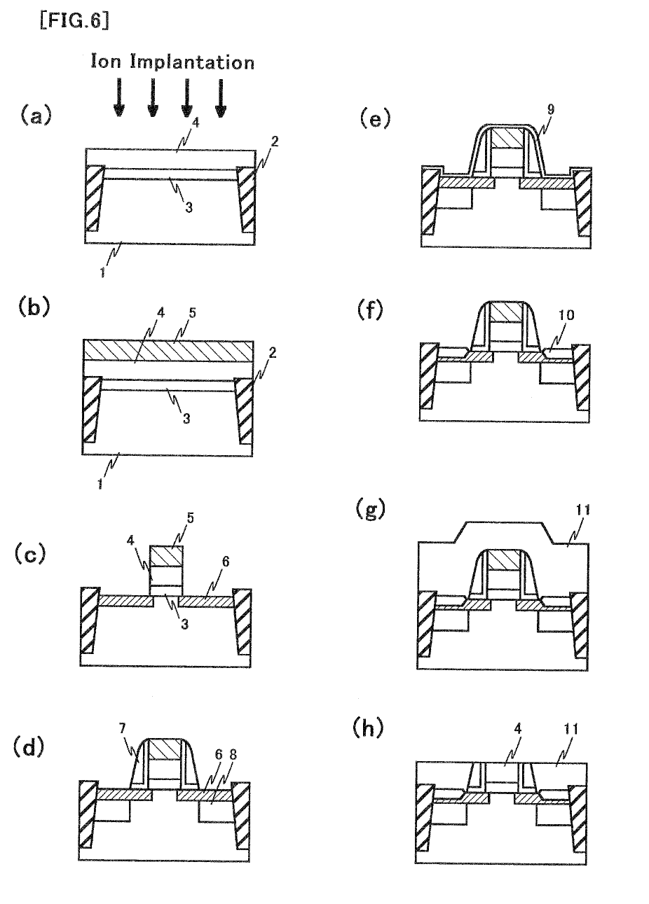

FIGS. 6A to 6H and FIGS. 7A to 7B are cross-sectional views each illustrating respective step in a method of fabricating the CMOSFET, in accordance with the third exemplary embodiment (for simplification, only steps for fabricating an NMOSFET are illustrated in FIGS. 6A to 6H and FIG. 7A).

First, as illustrated in FIG. 6A, the device separation area 2 was formed at a surface of the silicon substrate 1 through STI (Shallow Trench Isolation) process.

Then, the electrically insulating layer 3 was formed on a surface of the silicon substrate 1 in a region defined by the device separation area 2. The electrically insulating layer 3 was composed of SiON.

Then, as illustrated in FIG. 6A, a polysilicon (poly-Si) film 4 was formed on the electrically insulating layer 3 by the thickness of 80 nm.

Then, fluorine (F) was implanted into the polysilicon (poly-Si) film 4 in a region in which the first gate electrode is to be fabricated, and boron (B) was implanted into the polysilicon (poly-Si) film 4 in a region in which the second gate electrode is to be fabricated, both through a photolithography process employing a resist, and ion implantation.

Fluorine (F) was implanted at implantation energy of 5 KeV and at a dose of 5×10¹⁵ cm⁻², and boron (B) was implanted at implantation energy of 2 KeV and at a dose of 6×10¹⁵ cm⁻².

Then, as illustrated in FIG. 6B, a silicon oxide film 5 was formed on the polysilicon (poly-Si) film 4 by the thickness of 150 nm.

Then, as illustrated in FIG. 6C, a multi-layered structure comprised of the electrically insulating layer 3, the polysilicon (poly-Si) film 4, and the silicon oxide film 5 was patterned by means of lithography and RIE (Reactive Ion Etching) to thereby form a gate insulating film, and a gate pattern formed on the gate insulating film and comprised of the first and second gate electrodes (FIG. 6C illustrates only the first gate electrode).

Then, impurity ions were implanted into the silicon substrate 1 to thereby form the extended diffusion layers 6 at a surface of the silicon substrate 1 in a self-align manner with the gate pattern being used as a mask.

Then, as illustrated in FIG. 6D, a silicon nitride film and a silicon oxide film were deposited in this order, which were then etched back to thereby form the gate sidewall spacer 7 around a sidewall of the gate pattern.

Then, the second ion implantation was carried out, and annealing for activating the implanted ions was carried out. Thus, there were formed the source/drain regions 8 below the extended diffusion layers 6.

Then, as illustrated in FIG. 6E, a metal film 9 was formed entirely on the substrate by sputtering by the thickness of 20 nm.

Then, as illustrated in FIG. 6F, salicidation was carried out to form a silicide layer 10 only above the source/drain regions 8 by the thickness of about 40 nm with the gate pattern, the gate sidewall spacers 7 and the device separation area 2 being used as a mask.

The silicide layer 10 was composed of Ni monosilicide (NiSi) which could minimize a contact resistance. As an alternative, the silicide layer 10 may be composed of Co silicide or Ti silicide.

Then, as illustrated in FIG. 6G, the interlayer insulating film 11 comprised of a silicon oxide film was formed entirely over the substrate by means of CVD (Chemical Vapor Deposition).

Then, as illustrated in FIG. 6H, the interlayer insulating film 11 was planarized by means of CMP. Then, the interlayer insulating film 11 was etched back to thereby cause the polysilicon (poly-Si) film 4 of the gate pattern to appear.

Then, as illustrated in FIG. 7A, in order to turn the polysilicon (poly-Si) film 4 of the gate pattern into silicide, a metal film 12 composed of a metal M was formed on the polysilicon (poly-Si) film 4 of the gate pattern, the gate sidewall spacer 7, and the interlayer insulating film 11.

The metal film 12 may be composed of a metal which can make silicide with the polysilicon (poly-Si) film 4. For instance, such a metal can be selected from nickel (Ni), platinum (Pt), tantalum (Ta), cobalt (Co), titanium (Ti) or alloys thereof. It is preferable to select a metal which can completely turn the polysilicon (poly-Si) film 4 into silicide at such a temperature that an electrical resistance of the silicide layer 10 having been formed above the source/drain regions 8 is not increased.

For instance, in the case that a Ni monosilicide (NiSi) layer was formed above the source/drain regions 8, in order to prevent a contact resistance between the source/drain regions 8 and a wire from raising when the polysilicon (poly-Si) film 4 is turned into Ni disilicide (NiSi₂), it is necessary to set a subsequent process temperature equal to or lower than 500 degrees centigrade. Accordingly, the metal film 12 in the third exemplary embodiment was composed of nickel (Ni) which sufficiently ensures silicidation at a temperature equal to or lower than 500 degrees centigrade.

The nickel film to be formed in this step is designed to have such a thickness that the polysilicon (poly-Si) film 4 and nickel sufficiently react with each other to ensure that the polysilicon (poly-Si) film 4 is entirely silicided into NiSi.

In the third exemplary embodiment, the nickel film was formed at a room temperature by DC magnetron sputtering by the thickness of 50 nm.

While the gate pattern is being turned into silicide, an impurity (for instance, fluorine) having been implanted into the NMOSFET gate pattern (polysilicon) is caused to be disposed at an interface between the gate electrode and the gate insulating film to thereby form an impurity layer 17, as illustrated in FIG. 7B.

Similarly, an impurity (for instance, boron) having been implanted into the PMOSFET gate pattern (polysilicon) is caused to be disposed at an interface between the gate electrode and the gate insulating film to thereby form an impurity layer 18, as illustrated in FIG. 7B.

Then, an excessive portion of the nickel film which did not make silicide in the thermal annealing was removed by wet etching employing sulfuric acid hydrogen peroxide aqueous solution.

By carrying out the above-mentioned steps, as illustrated in FIG. 7B, there were fabricated NMOSFET and PMOSFET including full silicide electrodes in which different impurities from each other exist at interfaces between each of the first and second gate electrodes 13 and 14, and the gate insulating film.

The XPS measurement was carried out to the thus fabricated NMOSFET to confirm that fluorine (F) as an impurity existed mainly at an interface between the first gate electrode 13 composed of NiSi and the gate insulating film composed of SiON.

Furthermore, a surface density of fluorine (F) as an impurity combined with oxygen existing in the gate insulating film comprised of a SiON film was calculated based on the results of the XPS measurement, and further, was measured through TEM-EELS. As a result, a surface density of fluorine (F) as an impurity calculated and measured based on the XPS measurement and TEM-EELS, respectively, was 9×10¹³ cm⁻², and an effective work function of the first gate electrode 13 was 4.05 eV.

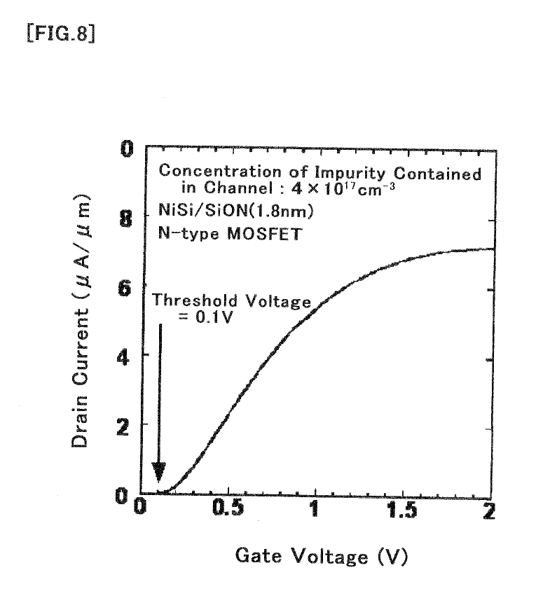

FIG. 8 is a graph of the measurement showing the dependency of a drain current on a gate voltage in an NMOSFET including a channel containing an impurity at a concentration of 4×10¹⁷ cm⁻³, and the first gate electrode 13 composed of NiSi having an effective work function of 4.05 eV.

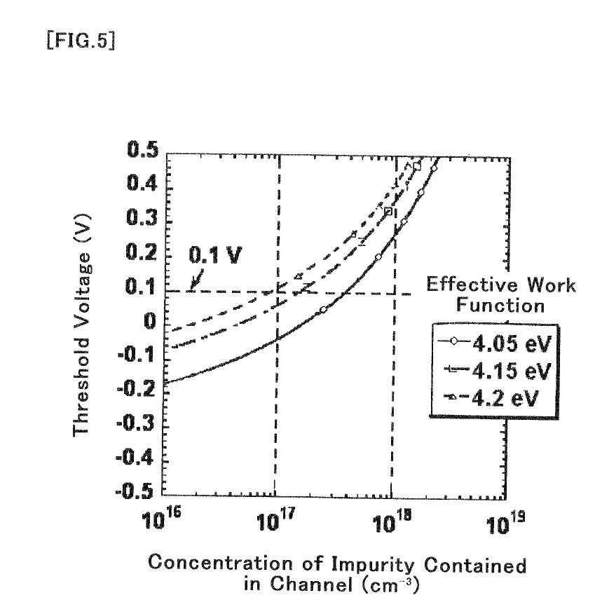

A threshold voltage (Vth) expected when an effective work function was equal to 4.05 eV was 0.1 V in view of FIG. 5. In accordance with the measurement shown in FIG. 8, a threshold voltage (Vth) of an NMOSFET including a gate electrode composed of NiSi is equal to 0.1 V, as having been expected based on the effective work function.

As mentioned above, it was confirmed that a combination of a NiSi electrode into which an impurity is implanted and a gate insulating film composed of SiON could provide superior transistor characteristics.

### Fourth Exemplary Embodiment

The fourth exemplary embodiment in accordance with the present invention relates to a method of fabricating the NMOSFET in accordance with the second exemplary embodiment, which is different from the method in accordance with the above-mentioned third exemplary embodiment.

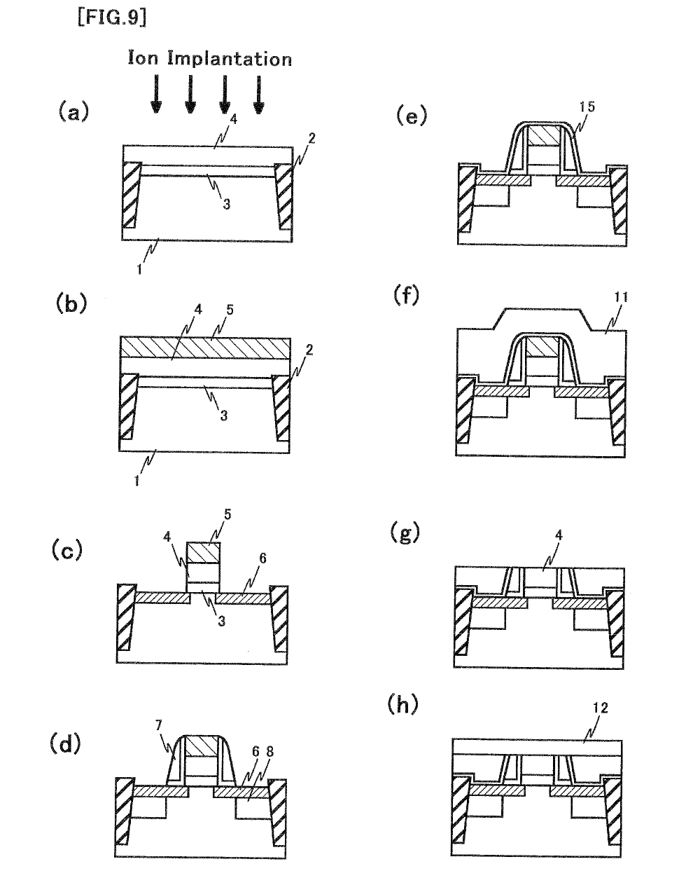

FIGS. 9A to 9H, FIGS. 10A to 10C, and FIGS. 11A to 11C are cross-sectional views each illustrating respective step in a method of fabricating the CMOSFET, in accordance with the fourth exemplary embodiment (for simplification, only steps for fabricating an NMOSFET are illustrated in FIGS. 9A to 9H).

The fourth exemplary embodiment is different from the third exemplary embodiment in that silicide is formed on source/drain regions after silicidation of a gate pattern was carried out, and that a silicon nitride film is formed to apply distortion to a channel region of an NMOSFET for enhancing electron mobility.

In the fourth exemplary embodiment, the same steps (FIGS. 9A to 9D) as those illustrated in FIGS. 7A to 7D in the third exemplary embodiment for forming source/drain regions are carried out. These steps are not explained, and the next step illustrated in FIG. 9E and subsequent steps are explained hereinbelow.

In the fourth exemplary embodiment, a gate pattern acting as a first gate electrode contains chlorine (Cl) as an impurity.

As illustrated in FIG. 9E, a silicon nitride film 15 was formed entirely on the substrate by CVD (Chemical Vapor Deposition). The silicon nitride film 15 protects the silicon substrate 1, the first gate electrode 13, the second gate electrode 14, and the gate sidewall spacers 7 when the interlayer insulating film 11 is removed by wet etching.

Then, as illustrated in FIG. 9F, the interlayer insulating film 11 comprised of a silicon oxide film was formed entirely on the silicon nitride film 15 by CVD (Chemical Vapor Deposition).

Then, as illustrated in FIG. 9G, the interlayer insulating film 11 was planarized by CMP. Then, the interlayer insulating film 11 was etched back to thereby cause the polysilicon (poly-Si) film 4 defining the gate pattern to appear.

Then, as illustrated in FIG. 9H, a metal layer 12 composed of a metal M was formed on the polysilicon (poly-Si) film 4, the gate sidewall spacers 7, and the interlayer insulating film 11 in order to turn the polysilicon (poly-Si) film 4 defining the gate pattern into silicide.

The metal film 12 may be composed of a metal which can make silicide with the polysilicon (poly-Si) film 4. For instance, such a metal can be selected from nickel (Ni), platinum (Pt), tantalum (Ta), cobalt (Co), titanium (Ti), tungsten (W) or alloys thereof.

In the fourth exemplary embodiment, unlike the third exemplary embodiment, a silicide layer is not yet formed on the source/drain regions 8 when the polysilicon (poly-Si) film 4 defining the gate pattern is turned into silicide. Accordingly, unless an impurity having been implanted into the source/drain regions and the channel region is not re-diffused, it is possible to select any conditions for carrying out thermal annealing for turning the gate pattern into silicide. Thus, it is possible to select silicide of which a gate electrode is composed among a broader range of silicide than the third exemplary embodiment.

In the fourth exemplary embodiment, as the metal M of which the metal layer 12 is composed, there is selected tungsten (W) which is turned into silicide at a relatively high temperature. A temperature at which tungsten (W) is turned into silicide is equal to or higher than 800 degrees centigrade.

Then, the polysilicon (poly-Si) of which the gate pattern is composed is caused to react with the metal M to thereby form silicide of the metal M (the first silicidation).

Then, an excessive portion of the tungsten film which did not make silicide in the thermal annealing (the first silicidation) was removed by wet etching.

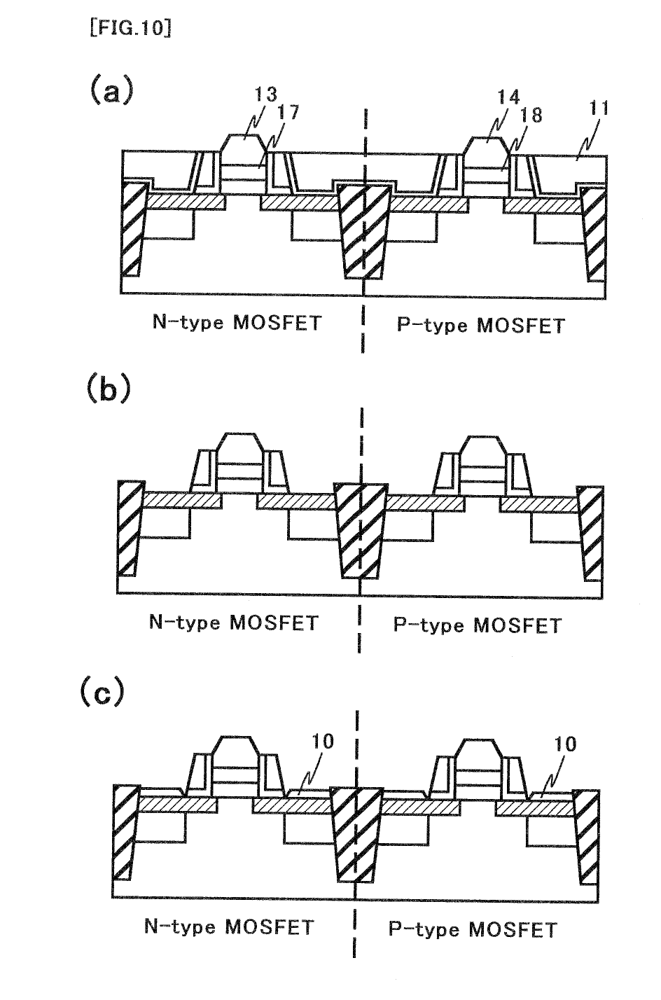

By carrying out the above-mentioned silicidation, as illustrated in FIG. 10A, an impurity (Cl) having been implanted into the NMOSFET gate pattern is caused to be disposed at an interface between the gate electrode 13 and the gate insulating film to thereby form an impurity layer 17.

Similarly, an impurity (for instance, boron) having been implanted into the PMOSFET gate pattern is caused to be disposed at an interface between the gate electrode 14 and the gate insulating film to thereby form an impurity layer 18, as illustrated in FIG. 10A.

Thus, there were fabricated the full silicide electrodes 13 and 14 containing different impurities from each other principally disposed at interfaces between the gate electrodes and the gate insulating film.

Then, as illustrated in FIG. 10B, the interlayer insulating film 11 was removed by hydrofluoric acid aqueous solution, and the silicon nitride film 15 was removed by phosphoric acid.

Then, as illustrated in FIG. 10C, a metal film was formed entirely over the substrate by sputtering by the thickness of 20 nm. Then, there was formed a silicide layer 10 only above the source/drain regions 8 by salicidation process by the thickness of about 40 nm with the gate pattern, the gate sidewall spacer 7, and the device separation area 2 being used as a mask (the third silicidation).

The silicide layer 10 was composed of Ni monosilicide (NiSi) which can minimize a contact resistance. In place of Ni silicide, the silicide layer 10 may be composed of Co silicide or Ti silicide.

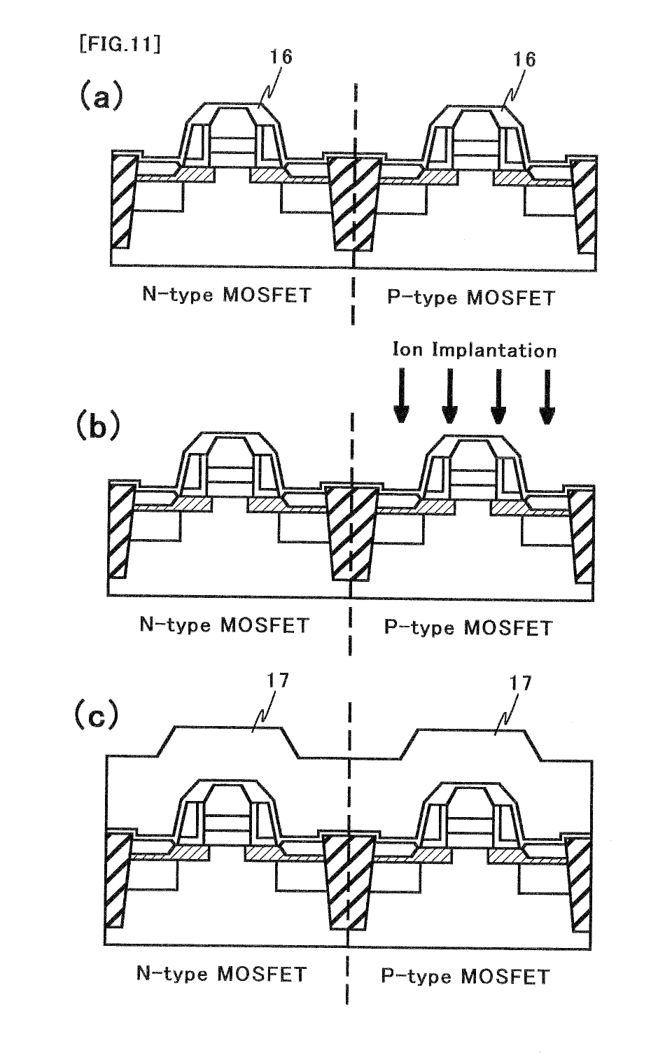

Then, as illustrated in FIG. 11A, there was formed a silicon nitride film 16 entirely over the substrate by CVD (Chemical Vapor Deposition) in order to apply tensile stress to an n-type channel to enhance electron mobility.

Then, as illustrated in FIG. 11B, a photolithography process employing a resist film, and ion implantation were carried out in combination to implant ions into the silicon nitride film 16 disposed in the PMOSFET for relaxing the stress in the silicon nitride film 16.

Then, as illustrated in FIG. 11C, there was formed an interlayer insulating film 19 entirely over the substrate by CVD (Chemical Vapor Deposition). The interlayer insulating film 19 was comprised of a silicon oxide film.

Then, there were formed wirings. Thus, there was fabricated the CMOSFET comprised of the NMOSFET including the full silicide electrode 13 containing a first impurity principally disposed at an interface between the gate electrode and the gate insulating film, and the PMOSFET including the full silicide electrode 14 containing a second impurity different from the first impurity, principally disposed at an interface between the gate electrode and the gate insulating film.

The XPS measurement was carried out to the thus fabricated NMOSFET to confirm that chlorine (Cl) was disposed principally at an interface between the gate electrode 13 comprised of a NiSi electrode and the gate insulating film comprised of a SiON film.

A surface density of the impurity (Cl) having combined with oxygen contained in the gate insulating film comprised of a SiON film was calculated based on the results of the XPS measurement, and furthermore, was measured by TEM-EELS.

The surface density of the impurity obtained by the XPS measurement and TEM-EELS was 1.3×10¹⁴ cm⁻², and the effective work function of the full silicide electrode 13 was 4.05 eV.

It was further confirmed that the NMOSFET in the fourth exemplary embodiment could have the same electron mobility as that of a transistor including a gate electrode composed of poly-Si and a gate insulating film composed of SiO₂.

As mentioned above, a combination of the NiSi electrode containing therein the impurity indicated in the fourth exemplary embodiment, and the gate insulating film composed of SiON could provide superior transistor characteristics.

While the present invention has been described in connection with certain exemplary embodiments, it is to be understood that the subject matter encompassed by way of the present invention is not to be limited to those specific embodiments. On the contrary, it is intended for the subject matter of the invention to include all alternatives, modifications and equivalents as can be included within the spirit and scope of the following claims.

For instance, as the metal M used for turning the gate pattern into silicide, there may be selected any metal, if it can turn the gate pattern into silicide at a temperature at which a resistance of metal silicide formed in a contact region disposed above source/drain regions is not increased, and it can form a full silicide gate electrode at the temperature. Accordingly, the metal M is not to be limited to Ni, but tantalum (Ta), platinum (Pt), cobalt (Co), titanium (Ti) or tungsten (W) may be used.

A combination of the metal M used for turning the gate electrode into silicide and a metal used for turning the source/drain regions into silicide is required to meet the condition that, as having been explained in the third exemplary embodiment, in the case that after formation of the source/drain regions, silicide is formed above the source/drain regions (the second silicidation), the combination can turn polysilicon (poly-Si) into full silicide at a temperature at which the silicide formed above the source/drain regions is not reformed.

Thus, even if it were difficult for a metal to turn a gate electrode into silicide at a low temperature, it would be possible to turn the gate electrode to silicide by carrying out thermal annealing for a long time. Accordingly, it is possible to completely turn a gate electrode into silicide by optimally determining conditions such as a temperature and a period of time at and during which thermal annealing is carried out, in dependence on a combination of silicide metal of which a gate electrode is composed, and silicide metal formed above source/drain regions.

Furthermore, for instance, by replacing polysilicon (poly-Si) formed on a gate electrode with amorphous Si, or by changing a temperature at which a metal film to be turned into silicide is formed, it is possible to lower a temperature at which silicidation is carried out. A preferable combination can be provided by combining these techniques with one another.

If it were necessary to reduce a gate leak current, there might be employed a gate insulating film having a high dielectric constant, such as a HfSiON film, in which case, a degree by which a threshold voltage is reduced is lowered in comparison which a case of using a gate insulating film comprised of a silicon oxide film or a silicon oxynitride film.

However, it is possible to lower an effective work function by designing a gate insulating film to have a multi-layered structure, inserting a silicon oxide layer, a silicon oxynitride layer or a silicon nitride layer into a portion at which the gate insulating film makes contact with a gate electrode, and forming a HfSiON layer below the gate insulating film. As a result, it is possible to accomplish an NMOSFET having a low threshold voltage.

The exemplary advantages obtained by the above-mentioned exemplary embodiments are described hereinbelow.

In accordance with the above-mentioned exemplary embodiments, at least one impurity selected from a group consisting of sulfur (S), fluorine (F) and chlorine (Cl) is caused to exist at a surface of an NMOSFET gate electrode making contact with a gate insulating film. This makes it possible to lower a threshold voltage (Vth) of an NMOSFET, and accomplish an NMOSFET and a CMOSFET both having high reproducibility and reliability.

This application is based upon and claims the benefit of priority from Japanese Patent Application No. 2005-372462 filed on Dec. 26, 2005, the entire disclosure of which, including specification, claims, drawings and summary, is incorporated herein by reference in its entirety.

1. An NMOSFET including:
a semiconductor substrate;
a gate insulating film formed on said semiconductor substrate; and
a first gate electrode formed on said gate insulating film,
said first gate electrode is composed of suicide of a metal, and at least one element selected as an impurity from a group consisting of sulfur (S), fluorine (F) and chlorine (Cl), and
said impurity exists at least at an interface between said first gate electrode and said gate insulating film.

2. The NMOSFET as set forth in claim 1, wherein said gate insulating film is composed of oxide.

3. The NMOSFET as set forth in claim 1, wherein said gate insulating film is composed of one of silicon oxide and silicon oxynitride.

4. The NMOSFET as set forth in claim 1, wherein said gate insulating film is composed of HfSiON.

5. The NMOSFET as set forth in claim 1, wherein said gate insulating film has a multi-layered structure, and
said gate insulating film is comprised of:
a first layer formed in contact with said first gate electrode, and comprised of one of a silicon oxide layer, a silicon oxynitride layer, and a silicon nitride layer; and
a second layer formed below said first layer, and composed of HfSiON.

6. The NMOSFET as set forth in claim 1, wherein monovalent fluorine (F) existing at a surface making contact with said gate insulating film of said first gate electrode has a surface density at 9×10¹³ cm⁻² or greater.

7. The NMOSFET as set forth in claim 1, wherein monovalent sulfur (S) existing at a surface making contact with said gate insulating film of said first gate electrode has a surface density at 1.1×10¹⁴ cm⁻² or greater.

8. The NMOSFET as set forth in claim 1, wherein monovalent chlorine (Cl) existing at a surface making contact with said gate insulating film of said first gate electrode has a surface density at 1.3×10¹⁴ cm⁻² or greater.

9. The NMOSFET as set forth in claim 1, wherein said metal is turned into silicide at a temperature in the range of 350 to 500 degrees centigrade both inclusive.

10. The NMOSFET as set forth in claim 1, wherein said metal is at least one metal selected from a group consisting of nickel (Ni), platinum (Pt), tantalum (Ta), cobalt (Co), titanium (Ti), and tungsten (W).

11. The NMOSFET as set forth in claim 1, wherein said metal is nickel (Ni).

12. The NMOSFET as set forth in claim 1, wherein said impurity is distributed upwardly from said interface in a direction of a normal line of said semiconductor substrate.

13. A CMOSFET including an NMOSFET, and a PMOSFET which includes a semiconductor substrate, a gate insulating film formed on said semiconductor substrate, and a second gate electrode formed on said gate insulating film,
wherein said NMOSFET includes a semiconductor substrate, a gate insulating film formed on said semiconductor substrate, and a first gate electrode formed on said gate insulating film,
said first gate electrode is composed of silicide of a metal, and at least one element selected as an impurity from a group consisting of sulfur (S), fluorine (F) and chlorine (Cl),
said impurity exists at least at an interface between said first gate electrode and said gate insulating film,
said NMOSFET and said PMOSFET are arranged such that length-wise directions of gates are parallel with each other,
said second gate electrode includes silicide of said metal, and an impurity, and
said first and second gate electrodes are electrically connected with each other, and define a line-shaped electrode extending perpendicularly to said length-wise direction of a gate of said NMOSFET.

14. A method of fabricating an NMOSFET, comprising:
a first step of forming an electrically insulating layer on a semiconductor substrate;
a second step of forming a polysilicon layer on said electrically insulating layer;
a third step of dosing at least one element selected as an impurity from a group consisting of sulfur (S), fluorine (F) and chlorine (Cl), into said polysilicon layer to thereby turn said polysilicon layer into an impurity-containing polysilicon layer;
a fourth step of patterning said electrically insulating layer and said impurity-containing polysilicon layer into a gate pattern;
a fifth step of depositing a metal layer on said gate pattern;
a sixth step of heating said metal and said impurity-containing polysilicon layer to thereby cause said metal to react with impurity-containing polysilicon included in said impurity-containing polysilicon layer, to thereby turn said metal into metal silicide containing an impurity therein; and
a seventh step of removing a portion of said metal which did not react with said impurity-containing polysilicon in said sixth step.

15. The method as set forth in claim 14, further comprising:
an eighth step of forming source/drain regions; and
a ninth step of forming silicide on said source/drain regions,
wherein said eighth and ninth steps are carried out prior to said sixth step,
said heating is carried out at said sixth step at such a temperature that an electrical resistance of said silicide formed on said source/drain regions is not raised.

16. The method as set forth in claim 14, further comprising:
a tenth step of forming source/drain regions prior to carrying out said sixth step; and
an eleventh step of forming silicide on said source/drain regions after said sixth step was carried out.

17. The method as set forth in claim 14, wherein said impurity is dosed into said polysilicon layer in said third step by ion implantation.

18. A method of fabricating a CMOSFET including an NMOSFET and a PMOSFET, comprising:
a first step of forming an electrically insulating layer on a semiconductor substrate;
a second step of forming a polysilicon layer on said electrically insulating layer;
a third step of dosing at least one element selected as an impurity from a group consisting of sulfur (S), fluorine (F) and chlorine (Cl), into said polysilicon layer in a region in which said NMOSFET is to be fabricated, to thereby turn said polysilicon layer into an impurity-containing polysilicon layer;
a fourth step of dosing a p-type impurity into said polysilicon layer in a region in which said PMOSFET is to be fabricated, to thereby turn said polysilicon layer into an impurity-containing polysilicon layer;
a fifth step of patterning said electrically insulating layer and said impurity-containing polysilicon layer into a gate pattern;
a sixth step of depositing a metal layer on said gate pattern;
a seventh step of heating said metal and said impurity-containing polysilicon layer to thereby cause said metal to react with impurity-containing polysilicon included in said impurity-containing polysilicon layer, to thereby turn said metal into metal silicide containing an impurity therein; and
an eighth step of removing a portion of said metal which did not react with said impurity-containing polysilicon in said seventh step.

19. The method as set forth in claim 18, wherein a first gate electrode of said NMOSFET and a second gate electrode of said PMOSFET are fabricated such that length-wise directions of gates of said NMOSFET and said PMOSFET are parallel with each other, and said first and second gate electrodes are electrically connected with each other, and define a line-shaped electrode extending perpendicularly to said length-wise direction of a gate of said NMOSFET.
